(19) United States
(12) Patent Application Publication
(10) Pub. No.: US 2026/0020278 A1
(43) Pub. Date: Jan. 15, 2026

(54) SEMICONDUCTOR DEVICE INCLUDING TWO-DIMENSIONAL MATERIAL AND METHOD OF FABRICATING THE SAME

(71) Applicants: Samsung Electronics Co., Ltd., Suwon-si (KR); KOREA ADVANCED INSTITUTE OF SCIENCE AND TECHNOLOGY, Daejeon (KR)

(72) Inventors: Minseok YOO, Suwon-si (KR); Kibum KANG, Daejeon (KR); Minseung GYEON, Daejeon (KR); Minsu SEOL, Suwon-si (KR)

(73) Assignees: Samsung Electronics Co., Ltd., Suwon-si, Gyeonggi-do (KR); KOREA ADVANCED INSTITUTE OF SCIENCE AND TECHNOLOGY, Daejeon (KR)

(21) Appl. No.: 19/264,049

(22) Filed: Jul. 9, 2025

(30) Foreign Application Priority Data
Jul. 10, 2024 (KR) 10-2024-0091358

(51) Int. Cl. H10D 30/47; H10D 30/01; H10D 62/17; H10D 62/80

(52) U.S. Cl. CPC H10D 30/481; H10D 30/017; H10D 62/883; H10D 62/292

(57) ABSTRACT

A semiconductor device and a method of fabricating the same are provided. The semiconductor device may include a source electrode, a drain electrode, an insulating region between the source electrode and the drain electrode, and a channel layer. The channel layer may be on the source electrode, the insulating region, and the drain electrode. The channel layer may include a source region on the source electrode, a drain region on the drain electrode, and a channel region on the insulating region. The source region and the drain region may include a precious metal element. The precious metal element in the drain region may be the same as the precious metal element in the source region. The channel region may include a first two-dimensional material layer having precious metal element-based semiconductor characteristics that may be the same as precious metal element-based semiconductor characteristics of the precious metal element.

### CROSS-REFERENCE TO RELATED APPLICATION

This application is based on and claims priority under 35 U.S.C. § 119 to Korean Patent Application No. 10-2024-0091358, filed on Jul. 10, 2024, in the Korean Intellectual Property Office, the disclosure of which is incorporated by reference herein in its entirety.

### BACKGROUND

### 1. Field

The present disclosure relates to a semiconductor device including a two-dimensional material and/or a method of fabricating the same.

### 2. Description of the Related Art

Transistors may be semiconductor devices that act as electrical switches. Transistors may be used in various semiconductor products, such as memories and/or semiconductor products for driving integrated circuits (ICs). As the size of semiconductor devices decreases, the number of semiconductor devices that can be integrated on one wafer may increase and/or the driving speed of semiconductor devices may increase. Research is being conducted to reduce the size of semiconductor devices.

Recently, research using two-dimensional materials is being conducted as a way to reduce the size of semiconductor devices. Because they may have stable and/or desired characteristics even at thicknesses of 1 nm or less, two-dimensional materials are being studied as materials capable of overcoming the limitations of performance degradation due to the decrease in the size of semiconductor devices.

### SUMMARY

Provided are a semiconductor device including a channel region in which a two-dimensional material layer having semiconductor characteristics based on a precious metal element is selectively grown on a substrate including heterogeneous materials, and/or a method of fabricating the same.

Additional aspects will be set forth in part in the description which follows and, in part, will be apparent from the description, or may be learned by practice of the presented embodiments of the disclosure.

According to an embodiment, a semiconductor device may include a source electrode; a drain electrode spaced apart from the source electrode; an insulating region of a substrate, the insulating region between the source electrode and the drain electrode; and a channel layer on the source electrode, the insulating region, and the drain electrode. The channel layer may include a source region on the source electrode, a drain region on the drain electrode, and a channel region on the insulating region. The source region and the drain region may include a precious metal element. The precious metal element in the drain region may be the same as the precious metal element in the source region. The channel region may include a first two-dimensional material layer having precious metal element-based semiconductor characteristics that may be the same as precious metal element-based semiconductor characteristics of the precious metal element.

In some embodiments, an arrangement of the precious metal element may be connected in a region in which at least one of the source region and the drain region may be in contact with the channel region.

In some embodiments, a grain size of the channel region may be larger than at least one of a grain size of the source region and a grain size of the drain region.

In some embodiments, the first two-dimensional material layer may include one of Pt, Ru, Rh, Pd, Ag, Os, Ir, and Au; and one of S, Se, and Te.

In some embodiments, a thickness of the channel region may be equal to a thickness of the source region, or a difference between the thickness of the channel region and the thickness of the source region may be greater than 0 nm and less than or equal to 50 nm.

In some embodiments, each of the source region and the drain region may include a precious metal layer including the precious metal element and having conductor characteristics; and a second two-dimensional material layer having semiconductor characteristics based on the precious metal element.

In some embodiments, a material of the first two-dimensional material layer may be the same as a material of the second two-dimensional material layer, and a number of layers of the first two-dimensional material layer is greater than a number of layers of the second two-dimensional material layer.

In some embodiments, the first two-dimensional material layer may extend in a direction parallel to the insulating region, a first end of the first two-dimensional material layer may form an edge contact with the source region, and a second end of the first two-dimensional material layer may form an edge contact with the drain region.

In some embodiments, a thickness of the second two-dimensional material layer may be smaller than a thickness of the precious metal layer.

In some embodiments, the semiconductor device may further include a first oxide layer between the source region and the source electrode, the first oxide layer including a metal oxide; and a second oxide layer between the drain region and the drain electrode, the second oxide layer including a metal oxide.

In some embodiments, at least a portion of the source region and the source electrode and at least a portion of the drain region and the drain electrode each may include an alloy layer including the precious metal element.

In some embodiments, the insulating region may protrude upward from upper surfaces of the source electrode and the drain electrode and the channel region covers three surfaces of the insulating region and surrounds the insulating region, of the insulating region may have a concave structure defined by a surface of the insulating region being concave downward from the upper surfaces of the source electrode and the drain electrode, and the channel region covers three surfaces of the insulating region having the concave structure.

In some embodiments, the semiconductor device may further include a gate insulating layer on the channel layer; and a gate electrode on the gate insulating layer.

In some embodiments, an electronic device may include semiconductor device.

According to an embodiments, a method of fabricating a semiconductor device may include preparing a substrate including an insulating region is between a source electrode and a drain electrode; forming a channel material layer including a precious metal element on the source electrode, the insulating region, and the drain electrode; and chalcogenizing the channel material layer, the chalcogenizing the channel material layer including forming a channel layer including a first two-dimensional material layer having precious metal element-based semiconductor characteristic. The channel layer may include a source region, a drain region, and a channel region. The source region may be on the source electrode and may include the precious metal element. The drain region may be on the drain electrode and may include the precious metal element. The channel region may be on the insulating region may include the first two-dimensional material layer having the precious metal element-based semiconductor characteristics.

In some embodiments, the chalcogenizing the channel material layer may include forming the first two-dimensional material layer extending in a direction parallel to the insulating region and forming the first two-dimensional material layer so both ends of the first-two dimensional material layer respectively have edge contacts a with the source region and the drain region.

In some embodiments, the chalcogenizing the chalcogenizing the channel material layer may include forming a second two-dimensional material layer in the source region and the drain region, and the second two-dimensional material layer may have precious metal element-based semiconductor characteristics.

In some embodiments, a number of layers of the first two-dimensional material layer may be greater than a number of layers of the second two-dimensional material layer.

In some embodiments, a thickness of the channel region may be equal to a thickness of the source region, or a difference between the thickness of the channel region and the thickness of the source region may be greater than 0 nm and less than or equal to 50 nm.

In some embodiments, the method may further include forming a gate electrode insulated from the channel region.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating a semiconductor device according to an embodiment;

FIG. 2 is an example of a cross-sectional view illustrating a portion of a semiconductor device with respect to a source electrode, a drain electrode, and a channel layer;

FIG. 3 is a diagram schematically illustrating an arrangement of elements in a channel region and a drain region in the channel layer of FIG. 2;

FIG. 4 is another example of a cross-sectional view illustrating a portion of a semiconductor device with respect to a source electrode, a drain electrode, and a channel layer;

FIG. 5 is another example of a cross-sectional view illustrating a portion of a semiconductor device with respect to a source electrode, a drain electrode, and a channel layer;

FIG. 6 is another example of a cross-sectional view illustrating a portion of a semiconductor device with respect to a source electrode, a drain electrode, and a channel layer;

FIG. 7 is another example of a cross-sectional view illustrating a portion of a semiconductor device with respect to a source electrode, a drain electrode, and a channel layer;

FIG. 8 is another example of a cross-sectional view illustrating a portion of a semiconductor device with respect to a source electrode, a drain electrode, and a channel layer;

FIG. 9 is another example of a cross-sectional view illustrating a portion of a semiconductor device with respect to a source electrode, a drain electrode, and a channel layer;

FIG. 10 is a flowchart schematically illustrating a method of fabricating a semiconductor device, according to an embodiment;

FIGS. 11A to 11C are diagrams schematically illustrating a method of fabricating a semiconductor device, according to an embodiment;

FIG. 12A is a diagram schematically showing a grain size of a channel material layer before chalcogenization proceeds; FIG. 12B is a diagram schematically showing a grain size of a channel material layer after chalcogenization proceeds; and

FIGS. 13 and 14 are conceptual diagrams schematically illustrating electronic device architectures applicable to electronic devices, according to embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., +10%).

Hereinafter, embodiments will be described in detail with reference to the accompanying drawings. In the following drawings, the same reference numerals refer to the same components, and the size of each component in the drawings may be exaggerated for clarity and convenience of description. Embodiments described below are merely illustrative, and various modifications are possible from these embodiments.

Hereinafter, the term “upper portion” or “on” may also include “to be present on the top, bottom, left or right portion on a non-contact basis” as well as “to be present just on the top, bottom, left or right portion in directly contact with”. The expression of the singular includes the expression of the plural, unless the context clearly indicates otherwise. In addition, when a part “contains” a component, this means that it may contain other components, rather than excluding other components, unless otherwise stated.

The use of the term “the” and similar indicative terms may correspond to both singular and plural. Unless there is clear order or contrary description of the steps constituting the method, these steps may be performed in the appropriate order, and are not necessarily limited to the order described.

Further, the terms “unit”, “module” or the like mean a unit that processes at least one function or operation, which may be implemented in hardware or software or implemented in a combination of hardware and software.

The connection or connection members of lines between the components shown in the drawings exemplarily represent functional connection and/or physical or circuit connections, and may be replaceable or represented as various additional functional connections, physical connections, or circuit connections in an actual device.

The use of all examples or illustrative terms is simply to describe technical ideas in detail, and the scope is not limited due to these examples or illustrative terms unless the scope is limited by the claims.

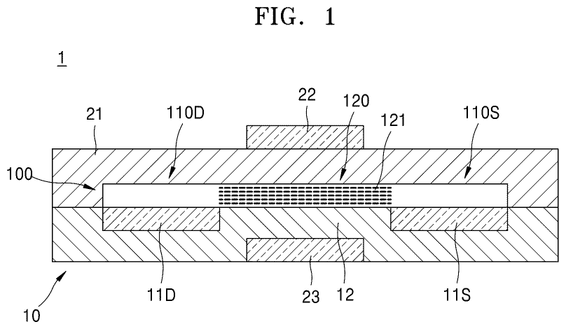

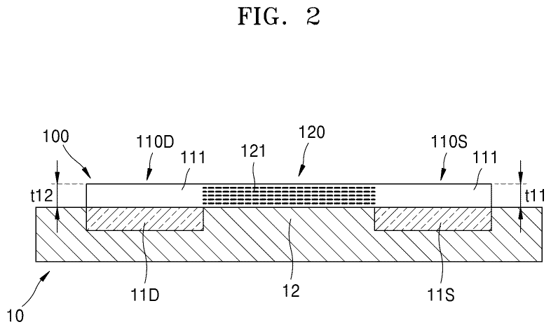

FIG. 1 is a cross-sectional view illustrating a semiconductor device 1 according to an embodiment. FIG. 2 is a cross-sectional view of the semiconductor device 1 of FIG. 1 with respect to a source electrode 11S, a drain electrode 11D, and a channel layer 100.

Referring to FIGS. 1 and 2, a semiconductor device 1 according to an embodiment may include a substrate 10 and a channel layer 100 arranged on the substrate 10.

The substrate 10 may include heterogeneous materials. For example, a portion of the substrate 10 may include a conductive material, and another portion of the substrate 10 may include an insulating material. For example, the substrate 10 may include a source electrode 11S, a drain electrode 11D, and an insulating region 12 arranged between the source electrode 11S and the drain electrode 11D.

The source electrode 11S and the drain electrode 11D may include a conductive material. The conductive material may include a doped semiconductor, a metal, a conductive metal nitride, a conductive metal oxide, a conductive metal silicide, a conductive metal carbide, or a combination of two or more thereof. For example, the conductive material may include silicon doped with an n-type or p-type dopant, tungsten, titanium, copper, aluminum, ruthenium, platinum, iridium, iridium oxide, tungsten nitride, titanium nitride, tantalum nitride, tungsten carbide, titanium carbide, tungsten silicide, titanium silicide, tantalum silicide, ruthenium oxide, or a combination of two or more thereof. The conductive material is not limited thereto as the conductive material is only an example, and may be variously modified.

At least a portion of the source electrode 11S may be in the substrate 10. The source electrode 11S may be in a groove on the substrate 10. At least a portion of the drain electrode 11D may be in the substrate 10. The drain electrode 11D may be in a groove on the substrate 10. However, the arrangement of the source electrode 11S and the drain electrode 11D is not limited thereto, and a structure in which the source electrode 11S and the drain electrode 11D are arranged to be spaced apart from each other on the substrate 10 may be variously modified.

The insulating region 12 may be between the source electrode 11S and the drain electrode 11D, and may include an insulating material. For example, the insulating region 12 may include an oxide insulating material. For example, the insulating region 12 may include silicon oxide. However, the material of the insulating region 12 is not limited thereto and may be variously modified.

The height of the top surface of the insulating region 12 may be the same as the height of the top surface of each of the source electrode 11S and the drain electrode 11D. The top surface of the source electrode 11S, the top surface of the insulating region 12, and the top surface of the drain electrode 11D may be arranged on the same plane. However, the top surface arrangement of the source electrode 11S, the insulating region 12, and the drain electrode 11D is not necessarily limited thereto, and the source electrode 11S, the insulating region 12, and the drain electrode 11D may be arranged on different planes.

The substrate 10 may further include, for example, an impurity region formed by doping, an electronic device such as a transistor, and/or peripheral circuit for selecting and controlling memory cells for storing data, or the like.

A channel layer 100 may be on the substrate 10. The channel layer 100 may provide a path through which a current flows between the source electrode 11S and the drain electrode 11D.

The channel layer 100 may be on the source electrode 11S, the insulating region 12, and the drain electrode 11D to connect the source electrode 11S and the drain electrode 11D to each. The channel layer 100 may include a source region 110S on the source electrode 11S, a channel region 120 on the insulating region 12, and a drain region 110D on the drain electrode 11D.

The channel layer 100 may include a precious metal element. The precious metal element may include at least one of Pt, Ru, Rh, Pd, Ag, Os, Ir, and Au.

The source region 110S may include a precious metal element. The source region 110S may be a conductive region including a precious metal element. The source region 110S may include a precious metal layer 111 including a precious metal element and having conductive characteristics. The precious metal element may include at least one of Pt, Ru, Rh, Pd, Ag, Os, Ir, and Au. The material of the source region 110S may be different from the material of the source electrode 11S, but is not necessarily limited thereto. In some embodiments, the material of the source region 110S may be the same as the material of the source electrode 11S.

The drain region 110D may include a precious metal element. The drain region 110D may include a precious metal layer 111 having conductive characteristics. The precious metal element may include at least one of Pt, Ru, Rh, Pd, Ag, Os, Ir, and Au. The drain region 110D may include the same precious metal element as the precious metal element of the source region 110S. The drain region 110D may be a conductive region including a precious metal element. The material of the drain region 110D may be different from the material of the drain electrode 11D, but is not necessarily limited thereto. In some embodiments, the material of the drain region 110D may be the same as the material of the drain electrode 11D

The channel region 120 may include a precious metal element. The channel region 120 may include a first two-dimensional material layer 121 having semiconductor characteristics based on a precious metal element. The first two-dimensional material layer 121 may include a two-dimensional semiconductor material based on a precious metal element. The first two-dimensional material layer 121 may have a layered structure in which constituent atoms are two-dimensionally bonded.

The first two-dimensional material layer 121 may include one precious metal element selected from the group consisting of Pt, Ru, Rh, Pd, Ag, Os, Ir, and Au, and one chalcogen element selected from the group consisting of S, Se, and Te. For example, the first two-dimensional material layer 121 may include PtS₂ or PtSe₂, but is not limited thereto.

The first two-dimensional material layer 121 may include a transition metal dichalcogenide (TMD). The first two-dimensional material layer 121 may include a material having a band gap of about 0.1 eV to about 3.0 eV.

The first two-dimensional material layer 121 may have a monolayer or multilayer structure where each layer may have an atomic level thickness. The first two-dimensional material layer 121 may include, for example, 1 to 10 layers. For example, the first two-dimensional material layer 121 may include 1 to 5 layers. For example, the first two-dimensional material layer 121 may include 1 to 3 layers. However, the number of layers of the first two-dimensional material layer 121 is only an example, and may be different depending on the material of the two-dimensional material layer.

Both ends of the first two-dimensional material layer 121 may be electrically connected to the source region 110S and the drain region 110D, respectively. The first two-dimensional material layer 121 may extend in a direction parallel to the insulating region 12. The first two-dimensional material layer 121 may extend in a direction parallel to the top surface of the insulating region 12. The first two-dimensional material layer 121 may have an edge contact structure in which both ends of the first two-dimensional material layer 121 are in contact with the source region 110S and the drain region 110D, respectively. In other words, the first two-dimensional material layer 121 may have a structure horizontally bonded to the source region 110S and the drain region 110D.

The channel region 120 may include the same precious metal element as the precious metal element of the source region 110S and the drain region 110D. For example, when the source region 110S and the drain region 110D include platinum (Pt), the two-dimensional material layer of the channel region 120 may include platinum selenium (PtSe₂), which is a platinum-based chalcogen compound.

An arrangement of precious metal elements may be connected in a region where at least one of the source region 110S and the drain region 110D comes into contact with the channel region 120, in the channel layer 100. In other words, the arrangement of the precious metal element in at least one of the source region 110S and the drain region 110D and the arrangement of the precious metal element in the channel region 120 may be connected to each other in the region where at least one of the source region 110S and the drain region 120 is in contact with the channel region 120. Here, the region where at least one of the source region 110S and the drain region 110D is in contact with the channel region 120 may be defined from a region within 5 nm of the channel region 120 from the boundary where the source region 110S or the drain region 110D is in contact with the channel region 120 to a region within 5 nm of the source region 110S or drain region 110D.

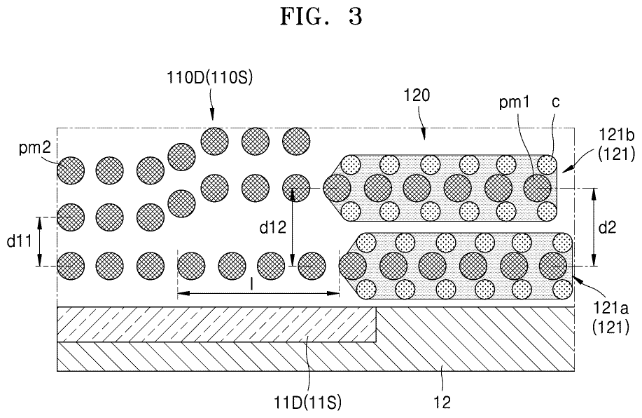

FIG. 3 is a diagram schematically illustrating an arrangement of elements in a channel region and a drain region in the channel layer 100 of FIG. 2.

Referring to FIG. 3, a plurality of first two-dimensional material layers 121 are stacked in a vertical direction in the channel region 120, and each of the first two-dimensional material layers 121 may include precious metal elements pm1 and chalcogen elements c. In the channel region 120, a distance d2 between each of the precious metal elements pm1 of the first two-dimensional material layer 121a located below and each of the precious metal elements pm1 of the first two-dimensional material layer 121b located above may be greater than a lattice constant of the precious metal element.

The drain region 110D may have the same precious metal element pm2 as the precious metal element pm1 of the channel region 120. In a region in which the drain region 110D and the channel region 120 are in contact with each other, the precious metal elements pm1 and pm2 may have an arrangement connected in a straight line within a range of 1 nm above and below. The precious metal elements pm2 of a region adjacent to the channel region 120 in the drain region 110D may have an arrangement connected to the precious metal elements pm1 in the channel region 120. A vertical distance d12 between the precious metal elements pm2 of a region adjacent to the channel region 120 in the drain region 110D may be greater than a vertical distance d11 between the precious metal elements pm2 of a region far from the channel region 120 in the drain region 110D. For example, the vertical distance d12 between the precious metal elements pm2 of a region adjacent to the channel region 120 in the drain region 110D is greater than the lattice constant of the precious metal element pm2, and the vertical distance d11 between the precious metal elements pm2 of a region far from the channel region 120 in the drain region 110D may correspond to the lattice constant of the precious metal element pm2. The length l of a region adjacent to the channel region 120 in the drain region 110D may be less than 10 nm.

The source region 110S may have the same precious metal elements pm2 as the precious metal elements pm1 of the channel region 120. In a region in which the source region 110S and the channel region 120 are in contact with each other, the precious metal elements pm1 and pm2 may have an arrangement connected in a straight line within a range of 1 nm above and below. The precious metal elements pm2 of a region adjacent to the channel region 120 in the source region 110S may have an arrangement connected to the precious metal elements pm1 in the channel region 120. The vertical distance d12 between the precious metal elements pm2 of a region adjacent to the channel region 120 in the source region 110S may be greater than the vertical distance d11 between the precious metal elements pm2 of a region far from the channel region 120 in the source region 110S. For example, the vertical distance d12 between the precious metal elements pm2 of a region adjacent to the channel region 120 in the source region 110S is greater than the lattice constant of the precious metal element pm2, and the vertical distance d11 between the precious metal elements pm2 of a region far from the channel region 120 in the source region 110S may correspond to the lattice constant of the precious metal element pm2. The length l of a region adjacent to the channel region 120 in the source region 110S may be less than 10 nm. Referring back to FIGS. 1 and 2, the source region 110S, the drain region 110D, and the channel region 120 of the channel layer 100 include the same precious metal element, but the source region 110S, the drain region 110D, and the channel region 120 of the channel layer 100 may differ in whether or not to include the first two-dimensional material layer 121 or the ratio of the first two-dimensional material layer 121.

The channel region 120, the source region 110S, and the drain region 110D may include the same precious metal elements, but may have different electrical characteristics. For example, the source region 110S and the drain region 110D may have conductor characteristics, and the channel region 120 may have semiconductor characteristics.

The thickness of the channel layer 100 may be less than or equal to a desired and/or alternatively predetermined thickness. The thickness of the channel layer 100 may be determined in consideration of the thickness for the channel region 120 to have semiconductor characteristics. The thickness of the channel layer 100 may be determined in consideration of the thickness for having semiconductor characteristics while the channel region 120 includes the first two-dimensional material layer 121 based on the precious metal element. The thickness of the channel layer 100 may be less than or equal to 3 nm. The thickness t12 of the channel region 120 may be less than or equal to 3 nm.

The channel region 120 may be formed together with the formation of the source region 110S and the drain region 110D. For example, after the channel region 120 is deposited together with the source region 110S and the drain region 110D, the first two-dimensional material layer 121 may be selectively formed in the channel region 120 deposited on the insulating region 12 during a chalcogenization process. A detailed process of forming the channel layer 100 will be described later.

As described above, as the channel region 120 is formed together with the source region 110S and the drain region 110D, the thickness of the channel region 120 may correspond to the thickness of the source region 110S and the thickness of the drain region 110D. For example, the thickness t12 of the channel region 120 may be the same as the thickness t11 of the source region 110S, or a difference therebetween may be within a desired and/or alternatively predetermined range. For example, the thickness t12 of the channel region 120 may be the same as the thickness t11 of the drain region 110D, or a difference therebetween may be within a desired and/or alternatively predetermined range. For example, a difference between the thickness t12 of the channel region 120 and the thickness t11 of the source region 110S (or the drain region 110D) may be 50 nm or less. For example, a difference between the thickness t12 of the channel region 120 and the thickness t11 of the source region 110S (or the drain region 110D) may be 1 nm or less. For example, a difference between the thickness t12 of the channel region 120 and the thickness t11 of the source region 110S (or the drain region 110D) may be 0.5 nm or less. For example, a difference between the thickness t12 of the channel region 120 and the thickness t11 of the source region 110S (or the drain region 110D) may be 33.3% or less of the thickness t12 of the channel region 120. For example, a difference between the thickness t12 of the channel region 120 and the thickness t11 of the source region 110S (or the drain region 110D) may be 16.6% or less of the thickness t12 of the channel region 120.

An example in which a two-dimensional material layer is formed only in the channel region 120 of the channel layer 100 has been described with reference to FIG. 2. However, the arrangement of the two-dimensional material layer of the channel layer 100 is not necessarily limited thereto, and may be various.

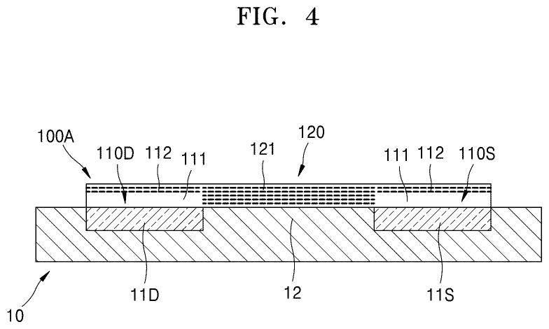

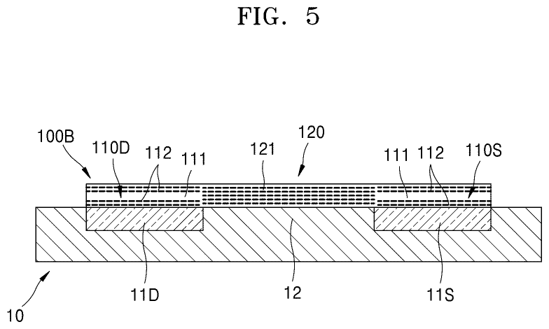

For example, as shown in FIGS. 4 and 5, a channel layer 100A may further include a second two-dimensional material layer 112 arranged in at least one of the source region 110S and the drain region 110D. Each of the source region 110S and the drain region 110D of the channel layer 100A may include a precious metal layer 111 including a precious metal element and having conductive characteristics, and a second two-dimensional material layer 112 having a precious metal element-based semiconductor characteristic.

The second two-dimensional material layer 112 may include a two-dimensional material having semiconductor characteristics based on precious metal elements included in each of the source region 110S and the drain region 110D.

The second two-dimensional material layer 112 may include one precious metal element selected from the group consisting of Pt, Ru, Rh, Pd, Ag, Os, Ir, and Au, and one chalcogen element selected from the group consisting of S, Se, and Te. For example, the second two-dimensional material layer 112 may include PtS₂ or PtSe₂, but is not limited thereto.

The material of the second two-dimensional material layer 112 may be the same as that of the first two-dimensional material layer 121. The precious metal elements included in the second two-dimensional material layer 112 may be the same as the precious metal elements included in the first two-dimensional material layer 121, and the chalcogen elements included in the second two-dimensional material layer 112 may be the same as the chalcogen elements included in the first two-dimensional material layer 121.

The second two-dimensional material layer 112 may have a monolayer or multilayer structure, and each layer may have an atomic level thickness. The second two-dimensional material layer 112 may include, for example, 1 to 5 layers. For example, the second two-dimensional material layer 112 may include 1 to 3 layers. For example, the second two-dimensional material layer 112 may include 1 to 2 layers.

The number of layers of the second two-dimensional material layer 112 may be less than that of the first two-dimensional material layer 121. For example, the number of layers of the second two-dimensional material layer 112 may be less than two-thirds (⅔) of that of the first two-dimensional material layer 121. For example, the number of layers of the second two-dimensional material layer 112 may be less than one-half (½) of that of the first two-dimensional material layer 121.

Each of the source region 110S and the drain region 110D may have conductor characteristics. For example, the thickness of the second two-dimensional material layer 112 may be less than the thickness of the precious metal layer 111. The thickness of the second two-dimensional material layer 112 may be equal to or less than one-half of the thickness of the precious metal layer 111. The thickness of the second two-dimensional material layer 112 may be equal to or less than one-third of the thickness of the precious metal layer 111.

The second two-dimensional material layer 112 may be arranged on at least one of the upper and lower portions of the source/drain regions 110S/110D.

For example, as shown in FIG. 4, the second two-dimensional material layer 112 may be arranged on the upper portions of the source region 110S and the drain region 110D. The channel layer 100A may have a planar contact in which the top surface of the precious metal layer 111, which is a portion that is not converted into the second two-dimensional material layer 112 in each of the source region 110S and the drain region 110D, is in contact with the second two-dimensional material layer 112.

As another example, as shown in FIG. 5, the second two-dimensional material layers 112 may be arranged on the upper portion of each of the source region 110S and the drain region 110D, and on the lower portion of each of the source region 110S and the drain region 110D, respectively. In a channel layer 100B, the second two-dimensional material layers 112 may have a planar contact with the precious metal layer 111, which is the remaining portion of each of the source region 110S and the drain region 110D, or may have a planar contact with the source electrode 11S and the drain electrode 11D. The second two-dimensional material layers 112 located on the lower portions of the source region 110S and the drain region 110D may have a planar contact with the source electrode 11S and the drain electrode 11D.

In FIG. 2, the source region 110S (or the drain region 110D) and the source electrode 11S (or the drain electrode 11D) are distinguished, and a structure in which the source region 110S (or the drain region 110D) and the source electrode 11S (or the drain electrode 11D) are in direct contact is illustrated. However, the structure of the source region 110S (or the drain region 110D) and the source electrode (11S) (or the drain electrode 11D) in the semiconductor device 1 is not necessarily limited thereto.

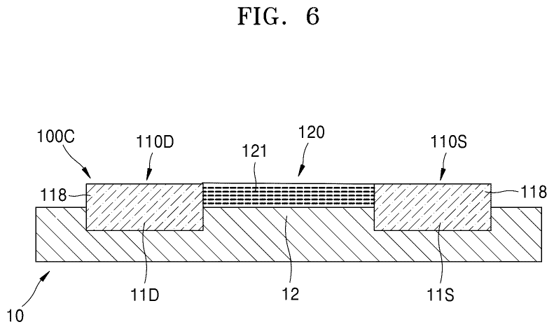

For example, as shown in FIG. 6, in a channel layer 100C, at least a portion of the source region 110S and the source electrode 11S may include an alloy layer containing a precious metal element, and at least a portion of the drain region 110D and the drain electrode 11D may include an alloy layer 118 containing a precious metal element.

The alloy layer 118 may be formed by reacting the source region 110S (or the drain region 110D) with the source electrode 11S (or the drain electrode 11D). For example, the source region 110S and the source electrode 11S may form one alloy layer 118, and the drain region 110D and the drain electrode 11D may form one alloy layer 118. However, the formation or arrangement of the alloy layer 118 is not limited thereto, and may be partially formed only near the interfacial portions between the source/drain region 110S/110D and the source/drain electrode 11S/11D depending on fabricating conditions.

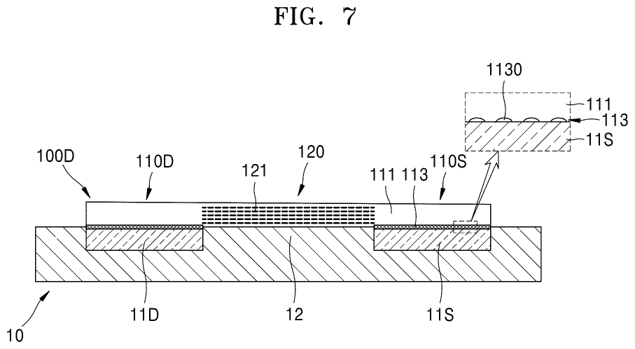

As another example, as shown in FIG. 7, an oxide layer 113 including a metal oxide may be formed on the source electrode 11S. The oxide layer 113 including a metal oxide may be arranged between the source region 110S and the source electrode 11S of a channel layer 100D. An oxide layer 113 including a metal oxide 1130 may be formed on the drain electrode 11D of the channel layer 100D. The oxide layer 113 including a metal oxide 1130 may be arranged between the drain region 110D and the drain electrode 11D.

The metal oxide 1130 may be partially arranged on the source electrode 11S (or the drain electrode 11D). The metal oxide 1130 may be partially arranged on the top surface of the source electrode 11S (or the drain electrode 11D), and a portion of the source region 110S (or the drain region 110D) may be in contact with the source electrode 11S (or the drain electrode 11D). For example, a metal oxide is formed in a dot form on the source electrode 11S (or drain electrode 11D), and the source region 110S (or drain region 110D) may be arranged between the dot-shaped metal oxides 1130. The source region 110S (or the drain region 110D) may partially contact the source electrode 11S (or the drain electrode 11D) despite the presence of the metal oxide.

The material of the metal oxide 1130 may vary according to the material of the source electrode 11S (or the drain electrode 11D) arranged thereunder. For example, the metal oxide 1130 may include a material of the source electrode 11S (or the drain electrode 11D).

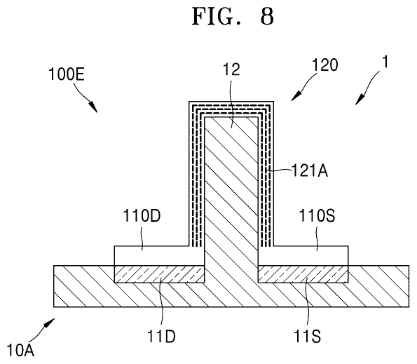

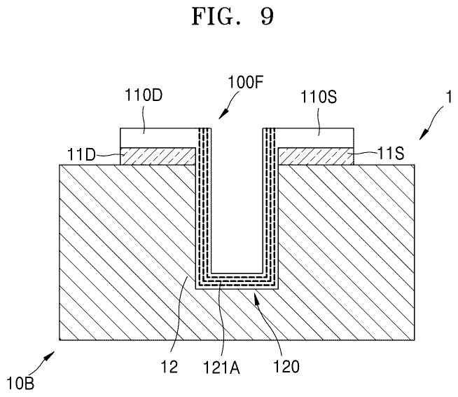

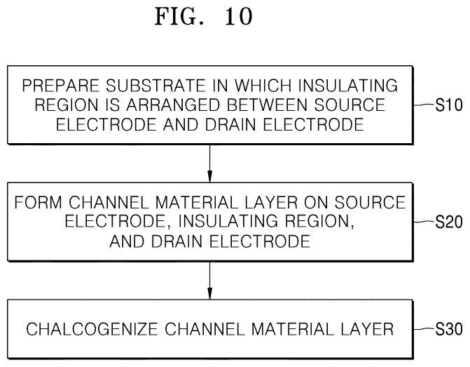

FIG. 8 is a diagram illustrating a portion of a semiconductor device 1 according to an embodiment. FIG. 9 is a diagram illustrating a portion of a semiconductor device 1 according to an embodiment. In FIG. 8 and FIG. 9, for convenience of description, the illustration of the gate insulating layer 21 and the gate electrode is omitted.

Referring to FIGS. 8 and 9, a semiconductor device 1 according to an embodiment may have a three-dimensional structure. For example, the substrates 10A and 10B may have a fin structure protruding upward from the upper surfaces of the source electrode 11S and the drain electrode 11D or a trench structure concave downward therefrom.

For example, as shown in FIG. 8, a semiconductor device 1 according to an embodiment may include a substrate 10A including an insulating region 12 having a pin structure, and a channel layer 100E including a channel region 120 surrounding three surfaces of the insulating region 12. The channel region 120 may include a first two-dimensional material layer 121A including a two-dimensional semiconductor material based on a precious metal element. The first two-dimensional material layer 121A may have a layered structure in which constituent atoms are two-dimensionally bonded. The first two-dimensional material layer 121A may have an edge contact structure in which both ends of the first two-dimensional material layer 121 are in contact with the source region 110S and the drain region 110D, respectively.

For example, as shown in FIG. 9, a semiconductor device 1 according to an embodiment may include a substrate 10B including an insulating region 12 having a trench structure, and a channel layer 100F including a channel region 120 surrounding three surfaces of the insulating region 12. The channel region 120 may include a first two-dimensional material layer 121A including a two-dimensional semiconductor material based on a precious metal element. The first two-dimensional material layer 121A may have a layered structure in which constituent atoms are two-dimensionally bonded. The first two-dimensional material layer 121A may have a planar contact in contact with the side surfaces of the source region 110S (or the drain region 110D) and the source electrode 11S (or the drain electrode 11D).

Referring back to FIG. 1, the semiconductor device 1 according to an embodiment may have a double gate structure. For example, the semiconductor device 1 may include the gate insulating layer 21 arranged on the channel layer 100, the first gate electrode 22 arranged on the gate insulating layer 21, and the second gate electrode 23 arranged under the substrate 10.

The gate insulating layer 21 may be arranged to cover the exposed surface of the channel region 120. The gate insulating layer 21 may be arranged to surround the channel layer 100. The gate insulating layer 21 may include, for example, silicon nitride, or the like, but is not limited thereto.

The first and second gate electrodes 22 and 23 may include a metal material or a conductive oxide. Here, the metallic material may include, for example, at least one selected from the group consisting of Au, Ti, TiN, TaN, W, Mo, WN, Pt, and Ni. In addition, the conductive oxide may include, for example, Indium Tin Oxide (ITO), Indium Zinc Oxide (IZO), etc. However, this is merely illustrative.

In the above-described embodiment, an example in which the semiconductor device 1 has a double gate structure has been mainly described, but embodiments of the semiconductor device 1 are not limited to the gate structure and may be various.

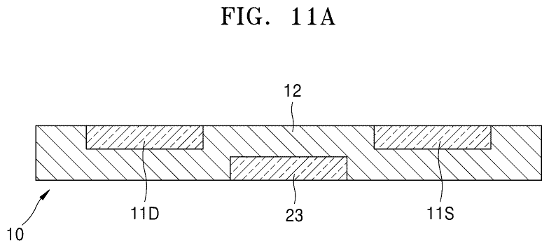

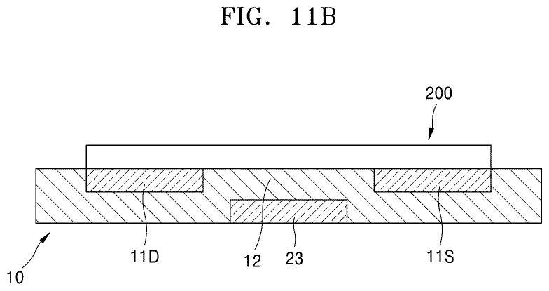

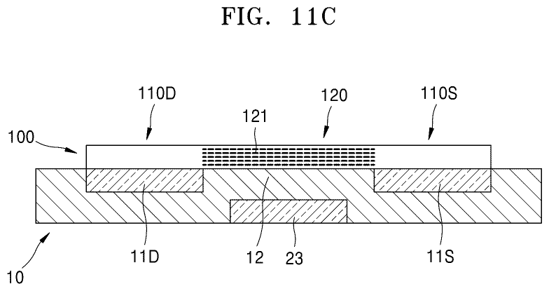

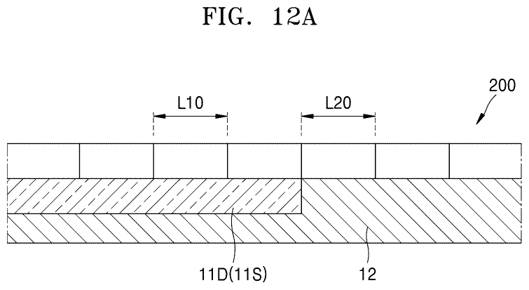

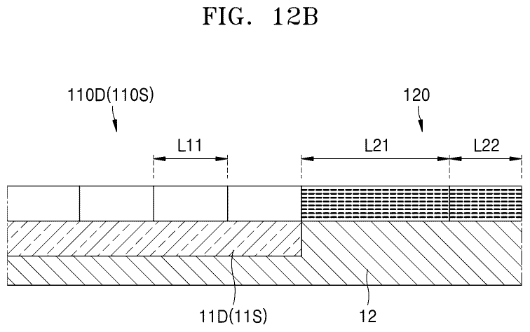

FIG. 10 is a flowchart schematically illustrating a method of fabricating a semiconductor device 1 according to an embodiment. FIGS. 11A to 11C are diagrams schematically illustrating a method of fabricating a semiconductor device 1 according to an embodiment. FIG. 12A is a diagram schematically showing a grain size of a channel material layer before chalcogenization proceeds, and FIG. 12B is a diagram schematically showing a grain size of a channel material layer after chalcogenization proceeds.

Referring to FIGS. 10 and 11A, in a method of fabricating a semiconductor device 1 according to an embodiment, a substrate 10 in which an insulating region 12 is arranged between a source electrode 11S and a drain electrode 11D is prepared (S10). A height of the top surface of each of the source electrode 11S and the drain electrode 11D may be the same as a height of the top surface of the insulating region 12.

The source electrode 11S and the drain electrode 11D may include a conductive material. The conductive material may include a doped semiconductor, a metal, a conductive metal nitride, a conductive metal oxide, a conductive metal silicide, a conductive metal carbide, or a combination of two or more thereof. For example, the conductive material may include silicon doped with an n-type or p-type dopant, tungsten, titanium, copper, aluminum, ruthenium, platinum, iridium, iridium oxide, tungsten nitride, titanium nitride, tantalum nitride, tungsten carbide, titanium carbide, tungsten silicide, titanium silicide, tantalum silicide, ruthenium oxide, or a combination of two or more thereof. The conductive material is not limited thereto as the conductive material is only an example, and may be variously modified.

The insulating region 12 is arranged between the source electrode 11S and the drain electrode 11D, and may include an insulating material. For example, the insulating region 12 may include an oxide insulating material. For example, the insulating region 12 may include silicon oxide. However, the material of the insulating region 12 is only an example, and may be variously modified.

Referring to FIGS. 10 and 11B, a channel material layer 200 may be formed on the substrate 10. The channel material layer 200 may be formed on the source electrode 11S, the insulating region 12, and the drain electrode 11D (S20). The channel material layer 200 may be deposited by chemical vapor deposition (CVD) or atomic layer deposition (ALD). However, the method of forming the channel material layer 200 is only an example and is not limited thereto.

The channel material layer 200 may include a precious metal element. The precious metal element may include at least one of Pt, Ru, Rh, Pd, Ag, Os, Ir, and Au.

In the channel material layer 200, portions arranged on the source electrode 11S, the insulating region 12, and the drain electrode 11D may include the same material. In other words, the material of the channel material layer 200 arranged on the source electrode 11S, the material of the channel material layer 200 arranged on the insulating region 12, and the material of the channel material layer 200 arranged on the drain electrode 11D may be in the same state.

Referring to FIGS. 11B and 12A, grain sizes L10 and L20 of portions of the channel material layer 200 arranged on the source electrode 11S, the insulating region 12, and the drain electrode 11D may be the same. For example, the grain size L10 of the channel material layer 200 on the source electrode 11S, the grain size L20 of the channel material layer 200 on the insulating region 12, and the grain size L10 of the channel material layer 200 on the drain electrode 11D may be in the same state. The grain sizes L10 and L20 of the channel material layer 200 may be less than or equal to a desired and/or alternatively predetermined size. For example, the grain sizes L10 and L20 of the channel material layer 200 may be 500 nm or less.

In the step of forming the channel material layer 200, the channel material layer 200 may be formed to have a desired and/or alternatively predetermined thickness or less. For example, the thickness of the channel material layer 200 may be determined in consideration of the thickness in which the channel region 120 of the channel layer 100 may have semiconductor characteristics. For example, the thickness of the channel material layer 200 may be less than or equal to 3 nm.

Referring to FIGS. 10 and 11C, the channel material layer 200 arranged on the substrate 10 may be selectively chalcogenized (S30).

The channel material layer 200 including a precious metal element may have a different chalcogenization rate depending on the material of the substrate 10 arranged below. For example, the chalcogenization rate of the channel material layer 200 placed on the insulating region 12 including an insulating material may be faster than the chalcogenization rate of the channel material layer 200 placed on the source electrode 11S or drain electrode 11D including a conductive material.

Due to the difference in the chalcogenization rates of the channel material layer 200, a two-dimensional material layer may be formed in the channel material layer 200 arranged on the insulating region 12, while a two-dimensional material layer may not be formed in the channel material layer 200 arranged on the source electrode 11S or the drain electrode 11D. Even if a two-dimensional material layer is formed in the channel material layer 200 arranged on the source electrode 11S or drain electrode 11D, a relatively large number of two-dimensional material layers may be formed in the channel material layer 200 arranged on the insulating region 12 due to a difference in the chalcogenization rates of the channel material layer 200, while a relatively small number of two-dimensional material layers may be formed in the channel material layer 200 arranged on the source electrode 11S or drain electrode 11D.

Due to the difference in chalcogenization rates, a two-dimensional material layer, for example, a first two-dimensional material layer 121 appears in the channel material layer 200 arranged on the insulating region 12, thereby changing from conductor characteristics to semiconductor characteristics. The channel material layer 200 arranged on the source electrode 11S and the drain region 110D may maintain conductor characteristics by appearing (or exhibiting) little or relatively little two-dimensional material layer, such as the second two-dimensional material layer 112.

The channel material layer 200 subjected to chalcogenization may be the channel layer 100. The channel layer 100 may include a source region 110S including a precious metal element, a drain region 110D including the same precious metal element as the precious metal element of the source region 110S, and a channel region 120 including at least one first two-dimensional material layer 121 including the semiconductor material based on the same precious metal element as the precious metal elements of the source region 110S and the drain region 110D.

Referring to FIG. 12B, in the chalcogenization process of the channel material layer 200 arranged on the insulating region 12, some grain sizes L22 of the channel material layer 200 may follow (or correspond) grain size L20 of the channel material layer 200 before chalcogenization, and some other grain may be combined with surrounding grains, so some other grain sizes L22 may be larger than the grain size L20 of the channel material layer 200 before chalcogenization.

The grain sizes L21 and L22 of the channel region 120 may be different from the grain size L11 of the source region 110S or the drain region 110D. For example, the grain size L21 of the channel region 120 may be larger than the grain size L11 of at least one of the source region 110S and the drain region 110D. For example, the grain size L21 in at least a portion of the channel region 120 may be larger than the grain size L11 in the source region 110S. For example, the grain size L21 in at least a portion of the channel region 120 may be larger than the grain size L11 in the drain region 110D.

The first two-dimensional material layer 121 may include one precious metal element selected from the group consisting of Pt, Ru, Rh, Pd, Ag, Os, Ir, and Au, and one chalcogen element selected from the group consisting of S, Se, and Te. For example, the first two-dimensional material layer 121 may include PtS₂ or PtSe₂, but is not limited thereto.

In the channel region 120, the first two-dimensional material layer 121 may extend in a direction parallel to the insulating region 12. In the process of forming the first two-dimensional material layer 121 in the channel region 120, both ends of the first two-dimensional material layer 121 may be connected to the source region 110S and the drain region 110D, respectively. Both ends of the first two-dimensional material layer 121 may be in contact with the source region 110S and the drain region 110D, respectively. The channel layer 100 may have an edge contact structure in which both ends of the channel region 120 are electrically connected to the source region 110S and the drain region 110D, respectively. Since the edge contact structure of the channel layer 100 appears in the chalcogenization process without a separate patterning process and a separate transfer process, deterioration of the quality of the channel layer 100 may be prevented. For example, the formation of defects at both ends of the channel region 120 may be minimized, and the occurrence of wrinkles or cracks may be reduced.

In the embodiment described with reference to FIGS. 11A to 11C, the source region 110S and the drain region 110D have been described based on an example in which the second two-dimensional material layer 112 is not formed in the source region 110S and the drain region 110D in a structure separated from the source electrode 11S and the drain electrode 11D, but the method of fabricating the semiconductor device 1 according to embodiments is not limited thereto. In the semiconductor device 1, whether the source region 110S (or the drain region 110D) and the source electrode 11S (or the drain electrode 11D) are distinguished and whether the second two-dimensional material layer 112 is formed may vary depending on process conditions such as the material, temperature, time, and precursor concentration of the source region 110S (or the drain electrode 11D) and the source electrode 11S (or the drain electrode 11D).

The semiconductor device 1 described above may be applied to, for example, a memory device such as a dynamic random access memory (DRAM) device. The memory device may have a structure in which the semiconductor device 1 and a capacitor are electrically connected to each other. In addition, the semiconductor device 1 may be applied to various electronic devices. For example, the semiconductor device 1 may be used for arithmetic operations, program execution, and temporary data retention in electronic devices such as mobile devices, computers, laptops, sensors, network devices, and neuromorphic devices.

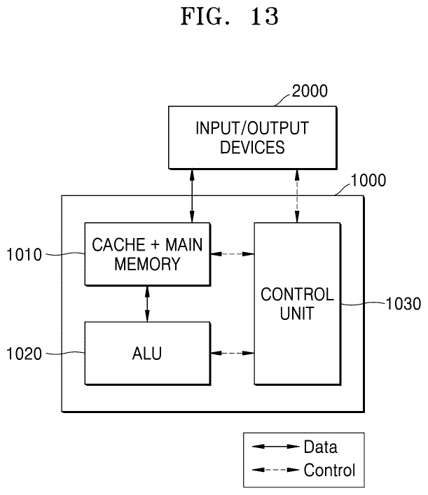

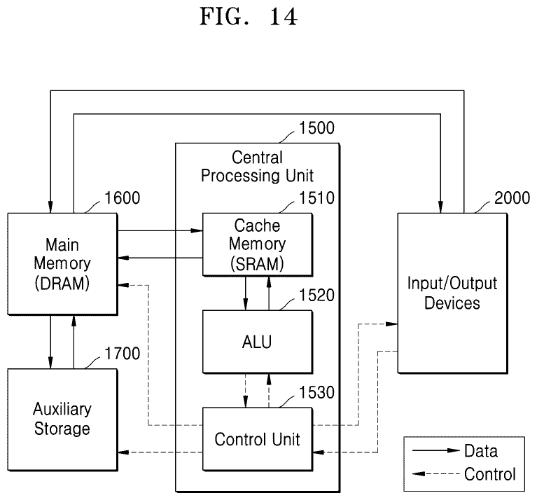

FIGS. 13 and 14 are conceptual diagrams schematically illustrating electronic device architectures applicable to electronic devices according to embodiments.

Referring to FIG. 13, an electronic device architecture (chip) 1000 may include a memory unit 1010, an arithmetical logic unit 1020, and a control unit 1030. The memory unit 1010, the ALU 1020, and the control unit 1030 may be electrically connected to each other. For example, the electronic device architecture (chip) 1000 may be implemented as a single chip including the memory unit 1010, the ALU 1020, and the control unit 1030.

Specifically, the memory unit 1010, the ALU 1020, and the control unit 1030 may be interconnected via metal lines on an on-chip to communicate directly with one another. The memory unit 1010, the ALU 1020, and the control unit 1030 may be monolithically integrated on one substrate to constitute one chip. Input/output devices (e.g., keyboard, display, mouse) 2000 may be connected to the electronic device architecture (chip) 1000.

Each of the ALU 1020 and the control unit 1030 may independently include the semiconductor device 1 described above, and the memory unit 1010 may include the semiconductor device 1 described above, a capacitor, or a combination thereof. The memory unit 1010 may include both a main memory and a cache memory. The electronic device architecture (chip) 1000 may be an on-chip memory processing unit.

Referring to FIG. 14, a cache memory 1510, an ALU 1520, and a control unit 1530 may constitute a central processing unit (CPU) 1500. The cache memory 1510 may include a static random access memory (SRAM), and may include any of the semiconductor devices 100 to 600 described above. A main memory 1600 and an auxiliary storage 1700 may be provided separately from the CPU 1500. The main memory 1600 may include a DRAM device.

In some cases, an electronic device architecture may be implemented in a form in which computing unit devices and memory unit devices are adjacent to each other in one chip without distinction of sub-units.

In a semiconductor device according to embodiments, a two-dimensional material layer with semiconductor characteristics based on precious metal elements is selectively grown on a source/drain electrode made of metals and an insulating region made of insulating materials, to form a channel region, thereby reducing contact resistance between the channel layer and the source/drain electrode.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a source electrode;
a drain electrode spaced apart from the source electrode;
an insulating region of a substrate, the insulating region between the source electrode and the drain electrode; and
a channel layer on the source electrode, the insulating region, and the drain electrode, wherein
the channel layer includes a source region on the source electrode, a drain region on the drain electrode, and a channel region on the insulating region,
the source region and the drain region include a precious metal element,
the precious metal element in the drain region is the same as the precious metal element in the source region, and
the channel region includes a first two-dimensional material layer having precious metal element-based semiconductor characteristics that are the same as precious metal element-based semiconductor characteristics of the precious metal element.

2. The semiconductor device of claim 1, wherein an arrangement of the precious metal element is connected in a region in which at least one of the source region and the drain region is in contact with the channel region.

3. The semiconductor device of claim 1, wherein a grain size of the channel region is larger than at least one of a grain size of the source region and a grain size of the drain region.

4. The semiconductor device of claim 1, wherein the first two-dimensional material layer includes:
one of Pt, Ru, Rh, Pd, Ag, Os, Ir, and Au; and
one of S, Se, and Te.

5. The semiconductor device of claim 1, wherein
a thickness of the channel region is equal to a thickness of the source region, or
a difference between the thickness of the channel region and the thickness of the source region is greater than 0 nm and less than or equal to 50 nm.

6. The semiconductor device of claim 1, wherein each of the source region and the drain region includes:
a precious metal layer including the precious metal element and having conductor characteristics; and
a second two-dimensional material layer having semiconductor characteristics based on the precious metal element.

7. The semiconductor device of claim 6, wherein
a material of the first two-dimensional material layer is the same as a material of the second two-dimensional material layer, and
a number of layers of the first two-dimensional material layer is greater than a number of layers of the second two-dimensional material layer.

8. The semiconductor device of claim 1, wherein
the first two-dimensional material layer extends in a direction parallel to the insulating region,
a first end of the first two-dimensional material layer forms an edge contact with the source region, and
a second end of the first two-dimensional material layer forms an edge contact with the drain region.

9. The semiconductor device of claim 6, wherein a thickness of the second two-dimensional material layer is smaller than a thickness of the precious metal layer.

10. The semiconductor device of claim 1, further comprising
a first oxide layer between the source region and the source electrode, the first oxide layer including a metal oxide; and
a second oxide layer between the drain region and the drain electrode, the second oxide layer including a metal oxide.

11. The semiconductor device of claim 1, wherein
at least a portion of the source region and the source electrode and at least a portion of the drain region and the drain electrode each include an alloy layer including the precious metal element.

12. The semiconductor device of claim 1, wherein
the insulating region protrudes upward from upper surfaces of the source electrode and the drain electrode and the channel region covers three surfaces of the insulating region and surrounds the insulating region, or
insulating region has a concave structure defined by a surface of the insulating region being concave downward from the upper surfaces of the source electrode and the drain electrode, and the channel region covers three surfaces of the insulating region having the concave structure.

13. The semiconductor device of claim 1, further comprising:
a gate insulating layer on the channel layer; and
a gate electrode on the gate insulating layer.

14. An electronic device including:
the semiconductor device of claim 1.

15. A method of fabricating a semiconductor device, the method comprising:
preparing a substrate including an insulating region is between a source electrode and a drain electrode;
forming a channel material layer including a precious metal element on the source electrode, the insulating region, and the drain electrode; and
chalcogenizing the channel material layer, the chalcogenizing the channel material layer including forming a channel layer including a first two-dimensional material layer having precious metal element-based semiconductor characteristics, wherein
the channel layer includes a source region, a drain region, and a channel region,
the source region is on the source electrode and includes the precious metal element,
the drain region is on the drain electrode and includes the precious metal element, and
the channel region is on the insulating region includes the first two-dimensional material layer having the precious metal element-based semiconductor characteristics.

16. The method of claim 15, wherein
the chalcogenizing the channel material layer includes forming the first two-dimensional material layer extending in a direction parallel to the insulating region and forming the first two-dimensional material layer so both ends of the first-two dimensional material layer respectively have edge contacts a with the source region and the drain region.

17. The semiconductor device of claim 15, wherein
the chalcogenizing the channel material layer includes forming a second two-dimensional material layer in the source region and the drain region, and
the second two-dimensional material layer has precious metal element-based semiconductor characteristics.

18. The method of claim 17, wherein a number of layers of the first two-dimensional material layer is greater than a number of layers of the second two-dimensional material layer.

19. The method of claim 15, wherein
a thickness of the channel region is equal to a thickness of the source region, or
a difference between the thickness of the channel region and the thickness of the source region is greater than 0 nm and less than or equal to 50 nm.

20. The method of claim 15, further comprising:
forming a gate electrode insulated from the channel region.
